(19) United States
(12) Patent Application Publication
(10) Pub. No.: US 2023/0217776 A1
(43) Pub. Date: Jul. 6, 2023

(54) Touch Display Apparatus

(71) Applicant: LG Display Co., Ltd., Seoul (KR)

(72) Inventors: Jae Won Lee, Paju-si (KR); Seung Hyun Youk, Paju-si (KR); Tae Gyu Lee, Paju-si (KR)

(21) Appl. No.: 17/980,202

(22) Filed: Nov. 3, 2022

(30) Foreign Application Priority Data
Dec. 31, 2021 (KR) 10-2021-0194801

(51) Int. Cl. H10K 59/40; H10K 59/131; G06F 3/041; G06F 3/044

(52) U.S. Cl. CPC H10K 59/40; H10K 59/131; G06F 3/0412; G06F 3/0446

(57) ABSTRACT

A touch display apparatus is provided. The touch display apparatus may include a touch sensor on an encapsulating layer that covers light-emitting devices. The touch sensor may include touch electrodes and bridge electrodes electrically connecting between the touch electrodes. Each of the touch electrodes may be electrically connected to a corresponding touch pad by one touch routing line from touch routing lines. The touch routing lines may include first routing lines and second routing lines disposed on a different layer from the first routing lines. Thus, in the touch display apparatus, an area occupied by the touch routing lines may be reduced.

### CROSS-REFERENCE TO RELATED APPLICATION

This application claims the benefit of Republic of Korea Patent Application No. 10-2021-0194801, filed on Dec. 31, 2021, which is hereby incorporated by reference in its entirety.

### BACKGROUND

### Field of Technology

The present disclosure relates to a touch display apparatus in which a touch sensor is disposed on an encapsulating unit covering light-emitting devices.

### Discussion of the Related Art

Generally, a display apparatus provides an image to user. For example, the display apparatus may include a plurality of light-emitting device. Each of the light-emitting devices may emit light displaying a specific color. For example, each of the light-emitting devices may include a light-emitting layer disposed between a first emission electrode and a second emission electrode.

The display apparatus may perform a specific program or apply a specific signal by a touch of user and/or a tool. For example, the display apparatus may be a touch display apparatus including a touch sensor. The touch sensor may be disposed on an encapsulating unit covering the light-emitting devices. For example, the touch sensor may include touch electrodes disposed side by side on the encapsulating unit and bridge electrodes electrically connecting between the touch electrodes.

Each of the touch electrodes may be electrically connected to the corresponding touch pad by one touch routing line from touch routing lines. A signal due to the touch of the user and/or the tool may transmit through the touch routing line electrically connected to the corresponding touch electrode. For example, the number of the touch routing lines may be proportional to the accuracy of the touch sensing. However, in the touch display apparatus, when the number of the touch routing lines increases, an area of a bezel area disposed outside a display area in which the light-emitting devices are disposed may also increase. Thus, an area of the display area may be reduced.

### SUMMARY

Accordingly, the present disclosure is directed to a touch display apparatus that substantially obviates one or more problems due to limitations and disadvantages of the related art.

An object of the present disclosure is to provide a touch display apparatus capable of improving the reliability for touch sensing, without reducing a display area.

Another object of the present disclosure is to provide a touch display apparatus capable of reducing an area occupied by touch routing lines.

Additional advantages, objects, and features of the disclosure will be set forth in part in the description which follows and in part will become apparent to those having ordinary skill in the art upon examination of the following or may be learned from practice of the disclosure. The objectives and other advantages of the disclosure may be realized and attained by the structure particularly pointed out in the written description and claims hereof as well as the appended drawings.

To achieve these objects and other advantages and in accordance with the purpose of the present disclosure, as embodied and broadly described herein, there is provided a touch display apparatus comprises: a plurality of light-emitting devices on a device substrate; an encapsulating layer on the plurality of light-emitting; a touch sensor including a plurality of touch electrodes on the encapsulating layer; a plurality of touch pads on the device substrate, the plurality of touch pads non-overlapping with the encapsulating layer; a plurality of touch routing lines, each touch routing line electrically connecting a corresponding touch electrode from the plurality of touch electrodes to a corresponding touch pad from the plurality of touch pads, wherein the plurality of touch routing lines include a plurality of first routing lines and a plurality of second routing lines that are on a different layer from the plurality of first routing lines, the plurality of second routing lines insulated from the plurality of first routing lines. c.

In one embodiment, a touch display apparatus comprising: a plurality of light-emitting devices on a device substrate; an encapsulating layer on the plurality of light-emitting devices; a plurality of touch pads on the device substrate, the plurality of touch pads non-overlapping with the encapsulating layer; a plurality of first touch lines on the encapsulating layer, the plurality of first touch lines including a plurality of first touch electrodes along in a first direction; a plurality of first routing lines, each first routing line electrically connecting a corresponding first touch line from the plurality of first touch lines to a corresponding touch pad from the plurality of touch pads; a plurality of second touch lines between the plurality of first touch lines, the plurality of second touch lines including a plurality of second touch electrodes that are connected in a second direction that is different from the first direction; and a plurality of second routing lines, each second routing line electrically connecting a corresponding second touch line from the plurality of second touch lines to a corresponding touch pad from the plurality of touch pads, wherein the plurality of second routing lines are on a different layer than the plurality of first routing lines.

In one embodiment, a touch display apparatus comprises: a substrate including a display area and a pad area; a plurality of pads in the pad area, the plurality of pads including a first pad and a second pad; a plurality of light-emitting devices on the display area; a touch sensor including a plurality of touch electrodes on the display area, the plurality of touch electrodes including a first touch electrode and a second touch electrode; a first routing line connected to the first touch electrode and the first touch pad; a second routing line connected to the second touch electrode and the second touch pad, wherein a portion of the first routing line at least partially overlaps a portion of the second routing line in a direction along a length of the display area in a plan view of the touch display apparatus.

### BRIEF DESCRIPTION OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIGS. 1 and 2 are views schematically showing a touch display apparatus according to an embodiment of the present disclosure;

FIG. 3 is an enlarged view of K region in FIG. 2 according to an embodiment of the present disclosure;

FIG. 4 is a view taken along I-I′ of FIG. 2 according to an embodiment of the present disclosure;

FIG. 5 is a view taken along II-II′ of FIG. 2 according to an embodiment of the present disclosure;

FIG. 6 is a view taken along of FIG. 3 according to an embodiment of the present disclosure;

FIG. 7 is a view showing the touch display apparatus according to another embodiment of the present disclosure; and

FIGS. 8 and 9 are views showing the touch display apparatus according to yet another embodiment of the present disclosure.

### DETAILED DESCRIPTION

Hereinafter, details related to the above objects, technical configurations, and operational effects of the embodiments of the present disclosure will be clearly understood by the following detailed description with reference to the drawings, which illustrate some embodiments of the present disclosure. Here, the embodiments of the present disclosure are provided in order to allow the technical sprit of the present disclosure to be satisfactorily transferred to those skilled in the art, and thus the present disclosure may be embodied in other forms and is not limited to the embodiments described below.

In addition, the same or extremely similar elements may be designated by the same reference numerals throughout the specification and in the drawings, the lengths and thickness of layers and regions may be exaggerated for convenience. It will be understood that, when a first element is referred to as being “on” a second element, although the first element may be disposed on the second element so as to come into contact with the second element, a third element may be interposed between the first element and the second element.

Here, terms such as, for example, “first” and “second” may be used to distinguish any one element with another element. However, the first element and the second element may be arbitrary named according to the convenience of those skilled in the art without departing the technical sprit of the present disclosure.

The terms used in the specification of the present disclosure are merely used in order to describe particular embodiments, and are not intended to limit the scope of the present disclosure. For example, an element described in the singular form is intended to include a plurality of elements unless the context clearly indicates otherwise. In addition, in the specification of the present disclosure, it will be further understood that the terms “comprises” and “includes” specify the presence of stated features, integers, steps, operations, elements, components, and/or combinations thereof, but do not preclude the presence or addition of one or more other features, integers, steps, operations, elements, components, and/or combinations.

And, unless ‘directly’ is used, the terms “connected” and “coupled” may include that two components are “connected” or “coupled” through one or more other components located between the two components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

### Embodiment

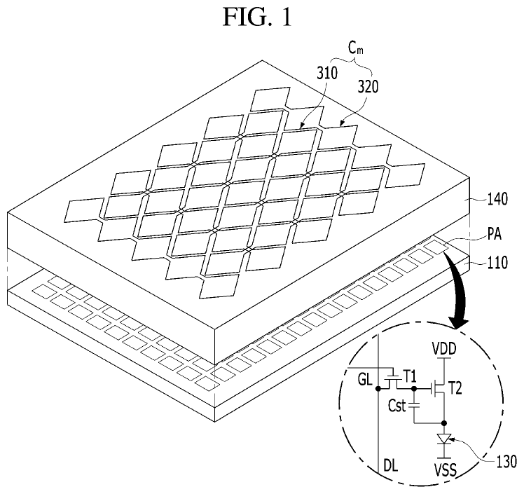

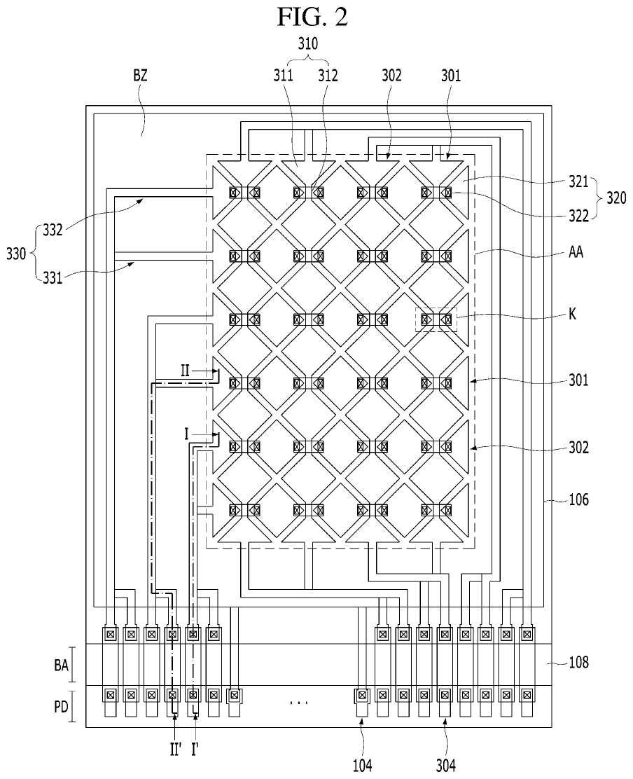

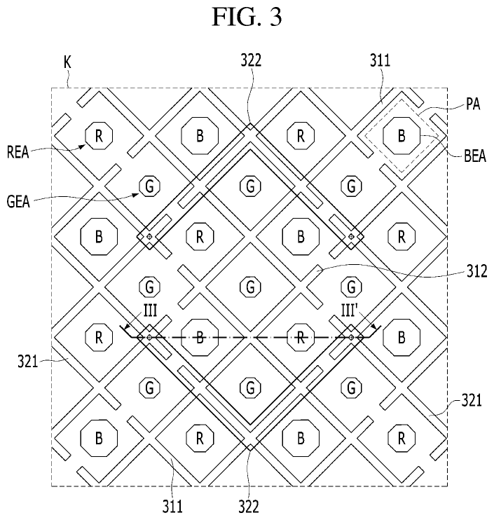

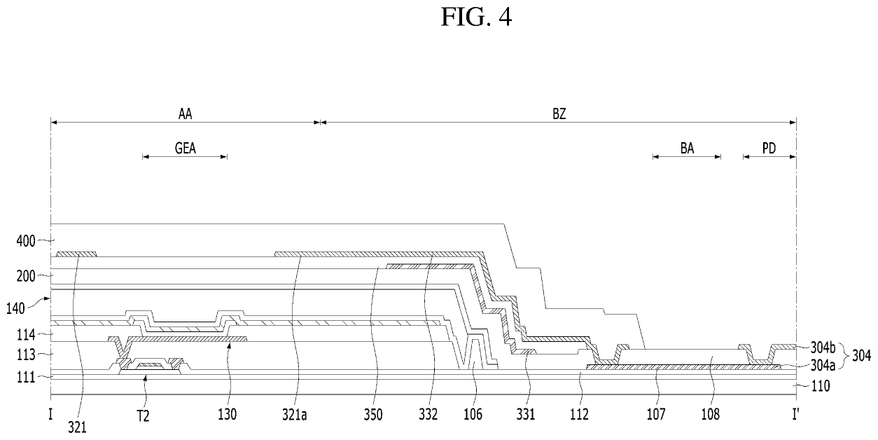

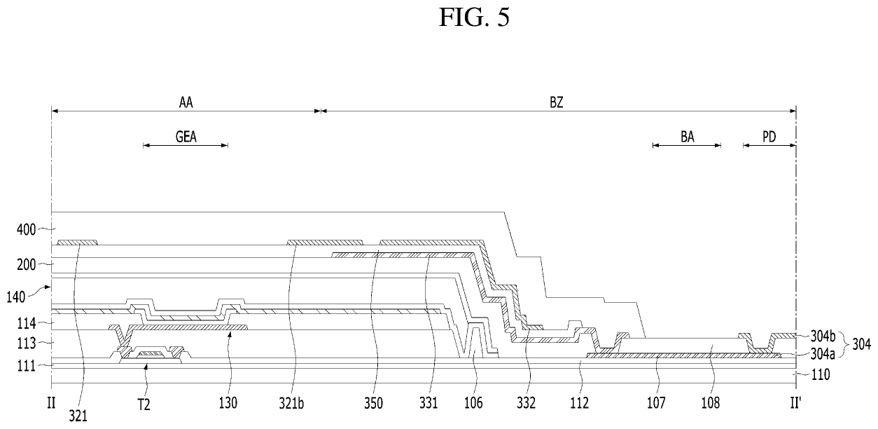

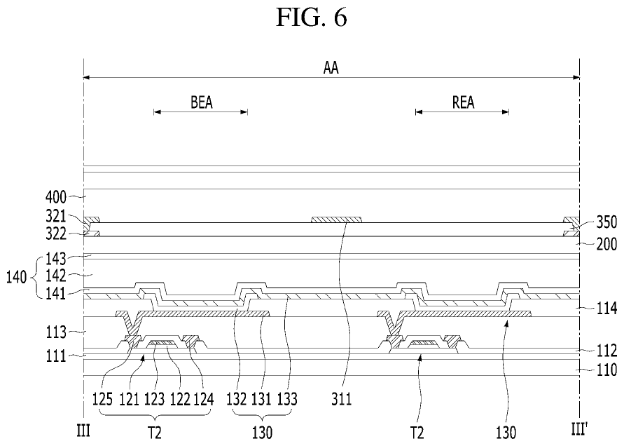

FIGS. 1 and 2 are views schematically showing a touch display apparatus according to an embodiment of the present disclosure. FIG. 3 is an enlarged view of K region in FIG. 2 according to an embodiment of the present disclosure. FIG. 4 is a view taken along I-I′ of FIG. 2 according to an embodiment of the present disclosure. FIG. 5 is a view taken along II-II′ of FIG. 2 according to an embodiment of the present disclosure. FIG. 6 is a view taken along of FIG. 3 according to an embodiment of the present disclosure.

Referring to FIGS. 1 to 6, the touch display apparatus according to the embodiment of the present disclosure may include a device substrate 110. The device substrate 110 may include an insulating material. For example, the device substrate 110 may include glass or plastic. The device substrate 110 may include a display area AA and a bezel area BZ disposed outside the display area AA. For example, the bezel area BZ may surround the display area AA.

Referring to FIG. 1, the display area AA of the device substrate 110 may display an image provided to user. For example, a plurality of pixel area PA may be disposed in the display area AA of the device substrate 110. The pixel areas PA may be disposed side by side in a first direction and a second direction that is perpendicular to the first direction. Two pixel areas PA adjacent in the first direction may be alternately disposed. Two pixel areas PA adjacent in the second direction may be alternately disposed. Each of the pixel areas PA may realize a color different from adjacent pixel areas PA. The touch display apparatus according to the embodiment of the present disclosure may have a pen-tile structure. For example, in the display area AA, the pixel areas PA may include first rows in which red pixel regions R and blue pixel regions B are alternately arranged and second rows in which green pixel regions G are arranged, wherein the first rows and the second rows are alternately disposed.

Light displaying a specific color may be emitted from each pixel area PA. For example, a pixel driving circuit and a light-emitting device 130 being electrically connected to the pixel driving circuit may be disposed in each pixel area PA.

The pixel driving circuit may be connected to one gate line of gate lines GL applying a gate signal and one data line of data lines DL applying a data signal. For example, the pixel driving circuit may generate a driving current corresponding to the data signal according to the gate signal. The driving current generated by the pixel driving circuit may provide the light-emitting device 130 for one frame. For example, the pixel driving circuit may include a switching thin film transistor T1, a driving thin film transistor T2, and a storage capacitor Cst.

The switching thin film transistor T1 may transmit the data signal to the driving thin film transistor T2 according to the gate signal. The driving thin film transistor T2 may generate the driving current. For example, the driving thin film transistor T2 may include a semiconductor pattern 121, a gate insulating layer 122, a gate electrode 123, a source electrode 124, and a drain electrode 125.

Referring to FIG. 6, the semiconductor pattern 121 may include a semiconductor material. For example, the semiconductor pattern 121 may include at least one of amorphous silicon, polycrystalline silicon, and oxide semiconductor. The semiconductor pattern 121 may include a source region, a drain region and a channel region. The channel region may be disposed between the source region and the drain region. The source region and the drain region may have a resistance lower than the channel region. For example, the source region and the drain region may include a conductorized region of oxide semiconductor.

The gate insulating layer 122 may be disposed on the semiconductor pattern 121. For example, the gate insulating layer 122 may overlap the channel region of the semiconductor pattern 121. The source region and the drain region of the semiconductor pattern 121 may be disposed outside the gate insulating layer 122. The gate insulating layer 122 may include an insulating material. For example, the gate insulating layer 122 may include an inorganic insulating material, such as silicon oxide (SiO) and silicon nitride (SiN).

The gate electrode 123 may be disposed on the gate insulating layer 122. For example, the gate electrode 123 may overlap the channel region of the semiconductor pattern 121. The gate electrode 123 may be insulated from the semiconductor pattern 121 by the gate insulating layer 122. For example, a side surface of the gate insulating layer 122 may be continuous with a side surface of the gate electrode 123. The gate electrode 123 may include a conductive material. For example, the gate electrode 123 may include a metal, such as aluminum (Al), titanium (Ti), copper (Cu), molybdenum (Mo), tantalum (Ta), chrome (Cr) and tungsten (W), or an alloy thereof. The gate electrode 123 may have a single-layer structure or a multi-layer structure. The channel region of the semiconductor pattern 121 may have an electric conductivity corresponding to a voltage applied to the gate electrode 123.

The source electrode 124 may include a conductive material. For example, the source electrode 124 may include a metal, such as aluminum (Al), titanium (Ti), copper (Cu), molybdenum (Mo), tantalum (Ta), chrome (Cr) and tungsten (W), or an alloy thereof. The source electrode 124 may have a single-layer structure or a multi-layer structure. The source electrode 124 may be insulated from the gate electrode 123. The source electrode 124 may be disposed on a layer different from the gate electrode 123. For example, an interlayer insulating layer 112 covering the gate electrode 123 may be disposed on the device substrate 110, and the source electrode 124 may be disposed on the interlayer insulating layer 112. The interlayer insulating layer 112 may include an insulating material. For example, the interlayer insulating layer 112 may include an inorganic insulating material, such as silicon oxide (SiO) and silicon nitride (SiN).

The source electrode 124 may be electrically connected to the source region of the semiconductor pattern 121. For example, the interlayer insulating layer 112 may include a source contact hole partially exposing the source region of the semiconductor pattern 121. The source electrode 124 may be in direct contact with the source region of the semiconductor pattern 121 through the source contact hole.

The drain electrode 125 may include a conductive material. For example, the drain electrode 125 may include a metal, such as aluminum (Al), titanium (Ti), copper (Cu), molybdenum (Mo), tantalum (Ta), chrome (Cr) and tungsten (W), or an alloy thereof. The drain electrode 125 may have a single-layer structure or a multi-layer structure. The drain electrode 125 may be insulated from the gate electrode 123. The drain electrode 125 may be disposed on a layer different from the gate electrode 123. For example, the drain electrode 125 may be disposed on the interlayer insulating layer 112. The drain electrode 125 may be disposed on the same layer as the source electrode 124. The drain electrode 125 may include the same material as the source electrode 124. For example, the drain electrode 125 may be formed simultaneously with the source electrode 124.

The drain electrode 125 may be electrically connected to the drain region of the semiconductor pattern 121. For example, the interlayer insulating layer 112 may include a drain contact hole partially exposing the drain region of the semiconductor pattern 121. The drain electrode 125 may be in direct contact with the drain region of the semiconductor pattern 121 through the drain contact hole.

The switching thin film transistor T1 may have the same structure as the driving thin film transistor T2. For example, the switching thin film transistor T1 may include a gate electrode electrically connected to the corresponding gate line GL, a source electrode electrically connected to the corresponding data line DL, and a drain electrode electrically connected to the gate electrode 123 of the driving thin film transistor T2. The source electrode 124 of the driving thin film transistor T2 may be electrically connected to a first power voltage supply line VDD supplying a positive power voltage. The storage capacitor Cst may maintain a signal applied to the gate electrode 123 of the driving thin film transistor T2 for one frame. For example, the storage capacitor Cst may be connected between the gate electrode 123 and the drain electrode 125 of the driving thin film transistor T2.

The light-emitting device 130 may emit light using the driving current supplied from the pixel driving circuit. For example, the light-emitting device 130 may include a first emission electrode 131, a light-emitting stack 132 and a second emission electrode 133, which are sequentially stacked on the device substrate 110.

The first emission electrode 131 may be electrically connected to the drain electrode 125 of the driving thin film transistor T2. For example, the driving current generated by the pixel driving circuit may be supplied to the first emission electrode 131 of the light-emitting device 130. The first emission electrode 131 may include a conductive material. The first emission electrode 131 may include a material having a high reflectance. For example, the first emission electrode 131 may be a metal, such as aluminum (Al), titanium (Ti), copper (Cu), molybdenum (Mo), tantalum (Ta), chrome (Cr) and tungsten (W), or an alloy thereof. The first emission electrode 131 may have a single-layer structure or a multi-layer structure. For example, the first emission electrode 131 may have a structure in which a reflective electrode made of a metal is disposed between transparent electrodes made of a transparent conductive material, such as ITO and IZO.

The light-emitting stack 132 may generate light having luminance corresponding to a voltage difference between the first emission electrode 131 and the second emission electrode 133. For example, the light-emitting stack 132 may include an emission material layer (EML) having an emission material. The emission material may include an organic material, an inorganic material or a hybrid material. For example, the touch display apparatus according to the embodiment of the present disclosure may be an organic light-emitting display apparatus including an organic emission material.

The light-emitting stack 132 may have a multi-layer structure. For example, the light-emitting stack 132 may further include at least one of a hole injection layer (HIL), a hole transport layer (HTL), an electron transport layer (ETL) and an electron injection layer (EIL). The light-emitting stack 132 may include a plurality of the emission material layer. For example, the light-emitting stack 132 may include a charge generation layer (CGL) between a first emission material layer and a second emission material layer. The second emission material layer may include a material different from the first emission material layer.

The second emission electrode 133 may include a conductive material. The second emission electrode 133 may have a transmittance higher than the first emission electrode 131. For example, the second emission electrode 133 may be a transparent electrode made of a transparent conductive material. The second emission electrode 133 may include a transparent conductive oxide material, such as ITO, IZO and AZO. Thus, in the touch display apparatus according to the embodiment of the present disclosure, the light generated by the light-emitting stack 132 of each pixel area PA may be emitted outside through the second emission electrode 133 of the corresponding pixel area PA.

Referring to FIGS. 4 to 6, a device buffer layer 111 may be disposed between the device substrate 110 and the pixel driving circuit of each pixel area PA. The device buffer layer 111 may prevent or at least reduce pollution due to the device substrate 110 in a process of forming the pixel driving circuits. The device buffer layer 111 may extend to the bezel area BZ of the device substrate 110. For example, an upper surface of the device substrate 110 toward the pixel driving circuit of each pixel area PA may be completely covered by the device buffer layer 111. The device buffer layer 111 may include an insulating material. For example, the device buffer layer 111 may include an inorganic insulating material, such as silicon oxide (SiO) and silicon nitride (SiN). The device buffer layer 111 may include a multi-layer structure. For example, the device buffer layer 111 may have a stacked structure of an inorganic insulating layer made of silicon oxide (SiO) and an inorganic insulating layer made of silicon nitride (SiN).

A planarization layer 113 may be disposed between the pixel driving circuit and the light-emitting device 130 of each pixel area PA. The planarization layer 113 may remove a thickness difference due to the pixel driving circuit of each pixel area PA. For example, an upper surface of the planarization layer 113 opposite to the device substrate 110 may be a flat surface. The switching thin film transistor T1, the driving thin film transistor T2 and the storage capacitor Cst in each pixel area PA may be covered by the planarization layer 113. The planarization layer 113 may include an insulating material. The planarization layer 113 may include a material different from the interlayer insulating layer 112. For example, the planarization layer 113 may include an organic insulating material.

The first emission electrode 131 of each pixel area PA may penetrate the planarization layer 113 to be electrically connected to the pixel driving circuit of the corresponding pixel area PA. For example, the planarization layer 113 may include pixel contact holes partially exposing the drain electrode 125 of the driving thin film transistor T2 in each pixel area PA. The first emission electrode 131 of each pixel area PA may be in direct contact with the drain electrode 125 of the driving thin film transistor T2 in the corresponding pixel area PA through one of the pixel contact holes.

The first emission electrode 131 of each pixel area PA may be insulated from the first emission electrode 131 of adjacent pixel area PA. The first emission electrode 131 of each pixel area PA may be spaced away from the first emission electrode 131 of adjacent pixel area PA. For example, a bank insulating layer 114 may be disposed between the first emission electrodes 131 of adjacent pixel areas PA. The bank insulating layer 114 may include an insulating material. For example, the bank insulating layer 114 may include an organic insulating material. The bank insulating layer 114 may cover an edge of the first emission electrode 131 in each pixel area PA. The light-emitting stack 132 and the second emission electrode 133 of each pixel area PA may be stacked on a portion of the corresponding first emission electrode 131 exposed by the bank insulating layer 114. For example, the bank insulating layer 114 may define an emission area BEA, GEA and REA in each pixel area PA.

The light-emitting device 130 of each pixel area PA may have the same structure as the light-emitting device 130 of adjacent pixel area PA. For example, the light-emitting stack 132 of each pixel area PA may extend along a surface of the bank insulating layer 114 to be connected to the light-emitting stack 132 of each pixel area PA. The light emitted from the light-emitting device 130 of each pixel area PA may display the same color as the light emitted from the light-emitting device 130 of adjacent pixel area PA. For example, the light-emitting stack 132 of each pixel area PA may emit white light. The light-emitting stack 132 of each pixel area PA may be formed simultaneously with the light-emitting stack 132 of adjacent pixel area PA. Thus, in the touch display apparatus according to the embodiment of the present disclosure, a process of forming the light-emitting stack 132 on each pixel area PA may be simplified.

A voltage applied to the second emission electrode 133 of each pixel area PA may be the same as a voltage applied to the second emission electrode 133 of adjacent pixel area PA. For example, the second emission electrode 133 of each pixel area PA may be electrically connected to a second power voltage supply line VSS supplying a negative power voltage. Thus, in the touch display apparatus according to the embodiment of the present disclosure, the luminance of the light emitted from the light-emitting device 130 of each pixel area PA may be adjusted by the data signal applied to the corresponding pixel area PA. The second emission electrode 133 of each pixel area PA may be electrically connected to the second emission electrode 133 of adjacent pixel area PA. For example, the second emission electrode 133 of each pixel area PA may be in direct contact with the second emission electrode 133 of adjacent pixel area PA. The second emission electrode 133 of each pixel area PA may be formed simultaneously with the second emission electrode 133 of adjacent pixel area PA. Therefore, in the touch display apparatus according to the embodiment of the present disclosure, a process of forming the second emission electrode 133 on each pixel area PA may be simplified.

An encapsulating unit 140 (e.g., an encapsulation layer) may be disposed on the light-emitting device 130 of each pixel area PA. The encapsulating unit 140 may prevent or at least reduce damage of the light-emitting devices 130 due to external moisture and/or oxygen. The light-emitting device of each pixel area PA may be completely covered by the encapsulating unit 140. For example, the encapsulating unit 140 may extend on the bezel area BZ of the device substrate 110.

The encapsulating unit 140 may include a plurality of encapsulation layers comprising at least one inorganic encapsulating layer 141 and 143, and at least one organic encapsulating layer 142. For example, the encapsulating unit 140 may have a structure in which at least one organic encapsulating layer 142 is disposed between inorganic encapsulating layers 141 and 143. The uppermost layer of the encapsulating unit 140 may be the inorganic encapsulating layers 141 and 143. For example, an upper surface and a side surface of the organic encapsulating layer 142 may be covered by the inorganic encapsulating layers 141 and 143. Thus, in the touch display apparatus according to the embodiment of the present disclosure, the penetration of the external moisture and oxygen may be effectively prevented or at least reduced.

The inorganic encapsulating layers 141 and 143 may include an inorganic insulating material. For example, the inorganic encapsulating layers 141 and 143 may include an inorganic insulating material capable of low-temperature deposition, such as silicon nitride (SiN), silicon oxide (SiO), silicon oxynitride (SiON) and aluminum oxide (Al₂O₃). Thus, in the touch display apparatus according to the embodiment of the present disclosure, the damage of the light-emitting stacks 132 due to a process of forming the inorganic encapsulating layer 141 and 143 may be blocked.

The organic encapsulating layer 142 may relieve the stress due to the inorganic encapsulating layer 141 and 143. For example, the organic encapsulating layer 142 may include an organic insulating material, such as acrylic resin, epoxy resin, polyimide, polyethylene and silicon oxycarbide (SiOC). A thickness difference due to the light-emitting devices 130 may be removed by the organic encapsulating layer 142. For example, an upper surface of the organic encapsulating layer 142 opposite to the device substrate 110 may be a flat surface.

The organic encapsulating layer 142 may be formed by inkjet process. For example, a dam 106 may be disposed on the bezel area BZ of the device substrate 110. The dam 106 may block the flow of the organic encapsulating layer 142. The dam 106 may extend along an edge of the display area AA. For example, in the touch display apparatus according to the embodiment of the present disclosure, the organic encapsulating layer 142 may be formed in a region defined by the dam 106. The dam 106 may be formed using a process of forming at least one of insulating layers, which are disposed between the device substrate 110 and the encapsulating unit 140. For example, the dam 106 may be formed simultaneously with the planarization layer 113. The dam 106 may include the same material as the planarization layer 113. For example, the dam 106 may include an organic insulating material. The interlayer insulating layer 112 may extend on the bezel area BZ of the device substrate 110. For example, the dam 106 may be disposed on the interlayer insulating layer 112. A thickness of the dam 106 may be the same as a thickness of the planarization layer 113.

A touch sensor Cm may be disposed on the encapsulating unit 140. The touch sensor Cm may sense a touch of user and/or a tool. For example, the touch sensor Cm may sense the presence or absence of a touch and a touch position by a change of the mutual capacitance. The touch sensor Cm may include a plurality of touch lines 310 and 320. For example, the touch sensor Cm may include driving touch lines 310 (e.g., a first touch electrode line) to which a touch driving signal is applied, and sensing touch lines 320 (e.g., a second touch electrode line) to which a touch sensing signal is applied.

Referring to FIGS. 2, 3 and 6, each of the driving touch lines 310 may include first touch electrodes 311 and first bridge electrodes 312. The first touch electrodes 311 may be disposed side by side on the encapsulating unit 140. The first bridge electrodes 312 may electrically connect between the first touch electrodes 311. Each of the first bridge electrodes 312 may extend in a first direction. For example, each of the driving touch lines 310 may include the first touch electrodes 311 connected in the first direction by the first bridge electrodes 312. In one embodiment, the first direction is a direction in which a length of the display area AA extends.

The first touch electrodes 311 may include a conductive material. The first touch electrodes 311 may include a material having a relatively low resistance. For example, the first touch electrodes 311 may include a metal, such as aluminum (Al), titanium (Ti), copper (Cu), molybdenum (Mo) and tantalum (Ta), or an alloy thereof. Each of the first touch electrodes 311 may have a single-layer structure or a multi-layer structure. For example, the first touch electrodes 311 may have a three-layer structure, such as Ti/Al/Ti, MoTi/Cu/MoTi and Ti/Al/Mo.

The first bridge electrodes 312 may include a conductive material. The first bridge electrodes 312 may include a material having a relatively low resistance. For example, the first bridge electrodes 312 may include a metal, such as aluminum (Al), titanium (Ti), copper (Cu), molybdenum (Mo) and tantalum (Ta), or an alloy thereof. The first bridge electrodes 312 may include the same material as the first touch electrodes 311. Each of the first bridge electrodes 312 may have a single-layer structure or a multi-layer structure. For example, the first bridge electrodes 312 may have a three-layer structure, such as Ti/Al/Ti, MoTi/Cu/MoTi and Ti/Al/Mo. The first bridge electrodes 312 may have the same structure as the first touch electrodes 311. The first bridge electrodes 312 may be disposed on the same layer as the first touch electrodes 311. For example, each of the first bridge electrodes 312 may be in direct contact with the corresponding first touch electrodes 311.

Each of the sensing touch lines 320 may include second touch electrodes 321 and second bridge electrodes 322. The second touch electrodes 321 may be disposed side by side on the encapsulating unit 140. The second touch electrodes 321 may be disposed on the same layer as the first touch electrodes 311. The second touch electrodes 321 may be insulated from the first touch electrodes 311. For example, the second touch electrodes 321 may be disposed between the first touch electrodes 311. The second touch electrodes 321 may have the same shape as the first touch electrodes 311. For example, the first touch electrodes 311 and the second touch electrodes 321 may be alternately arranged on the encapsulating unit 140. Thus, the touch display apparatus according to the embodiment of the present disclosure may sense the touch of the user and/or the tool using the driving touch lines 310 and the sensing touch lines 320 of the touch sensor Cm.

The second touch electrodes 321 may include a conductive material. The second touch electrodes 321 may include a material having a relatively low resistance. For example, the second touch electrodes 321 may include a metal, such as aluminum (Al), titanium (Ti), copper (Cu), molybdenum (Mo) and tantalum (Ta), or an alloy thereof. The second touch electrodes 321 may include the same material as the first touch electrodes 311. Each of the second touch electrodes 321 may have a single-layer structure or a multi-layer structure. For example, the second touch electrodes 321 may have a three-layer structure, such as Ti/Al/Ti, MoTi/Cu/MoTi and Ti/Al/Mo. The second touch electrodes 321 may have the same structure as the first touch electrodes 311.

The second touch electrodes 321 may be disposed on the same layer as the first touch electrodes 311 and the first bridge electrodes 312. The second touch electrodes 321 may be insulated from the first bridge electrodes 312. The second touch electrodes 321 may be spaced away from the first bridge electrodes 312. For example, the first bridge electrodes 312 may cross between the second touch electrodes 321.

The second bridge electrodes 322 may electrically connect between the second touch electrodes 321. Each of the second bridge electrodes 322 may extend in a second direction. For example, each of the sensing touch lines 320 may include the second touch electrodes 321 connected in the second direction by the second bridge electrodes 322. The second direction may be different from the first direction. For example, the second direction may be perpendicular to the first direction. The second bridge electrodes 322 may cross between the first touch electrodes 311. For example, each of the second bridge electrodes 322 may intersect one of the first bridge electrodes 312. The second bridge electrodes 322 may be insulated from the first bridge electrodes 312. The second bridge electrodes 322 may be disposed on a layer different from the first bridge electrodes 312. For example, the touch sensor Cm may include a touch insulating layer 350 on the second bridge electrodes 322, and the first touch electrodes 311, the first bridge electrodes 312 and the second touch electrodes 321 may be disposed on the touch insulating layer 350.

The touch insulating layer 350 may include an insulating material. For example, the touch insulating layer 350 may include an organic insulating material. Thus, in the touch display apparatus according to the embodiment of the present disclosure, the second bridge electrodes 322 may be effectively insulated from the first bridge electrodes 312. The touch insulating layer 350 may include touch contact holes partially exposing each second bridge electrode 322. Each of the second touch electrodes 321 may be connected to the corresponding second bridge electrode 322 through one of the touch contact holes.

The second bridge electrodes 322 may include a conductive material. The second bridge electrodes 322 may include a material having a relatively low resistance. For example, the second bridge electrodes 322 may include a metal, such as aluminum (Al), titanium (Ti), copper (Cu), molybdenum (Mo) and tantalum (Ta), or an alloy thereof. Each of the second bridge electrodes 322 may have a single-layer structure or a multi-layer structure. For example, the second bridge electrodes 322 may have a three-layer structure, such as Ti/Al/Ti, MoTi/Cu/MoTi and Ti/Al/Mo.

The first touch electrodes 311, the first bridge electrodes 312, the second touch electrodes 321 and the second bridge electrodes 322 of the touch sensor Cm may be disposed in the display area AA. The emission areas BEA, GEA and REA of each pixel area PA may be disposed between the first touch electrodes 311, the first bridge electrodes 312, the second touch electrodes 321 and the second bridge electrodes 322. The driving touch lines 310 and the sensing touch lines 320 may be disposed outside the light-emitting devices 130. That is, the driving touch lines 310 and the sensing touch lines 320 are non-overlapping with the light-emitting devices 130. For example, the first touch electrodes 311, the first bridge electrodes 312, the second touch electrodes 321 and the second bridge electrodes 322 may overlap the bank insulating layer 114. In a plan view, each of the first touch electrodes 311 and each of the second touch electrodes 321 may have a mesh shape including openings overlapping with the emission areas BEA, GEA and REA of each pixel area PA. Thus, in the touch display apparatus according to the embodiment of the present disclosure, the accuracy of the touch sensing using the touch sensor Cm may be improved, and the decrease in light extraction efficiency due to the touch sensor Cm may be reduced.

A touch buffer layer 200 may be disposed between the encapsulating unit 140 and the touch sensor Cm. For example, the second bridge electrodes 322 may be disposed between the touch buffer layer 200 and the touch insulating layer 350. The touch buffer layer 200 may reduce a parasitic capacitance generated between the second emission electrode 133 of each light-emitting device 130 and the touch sensor Cm. For example, a distance between each driving touch line 310 of the touch sensor Cm and the second emission electrode 133 of each light-emitting device 130 and a distance between each sensing touch line 320 of the touch sensor Cm and the second emission electrode 133 of each light-emitting device 130 may be increased by the touch buffer layer 200. Thus, in the touch display apparatus according to the embodiment of the present disclosure, the accuracy of the touch sensing by the touch sensor Cm may be improved. The touch buffer layer 200 may include an insulating material. For example, the touch buffer layer 200 may include an inorganic insulating material, such as silicon oxide (SiO) and silicon nitride (SiN).

A device passivation layer 400 may be disposed on the touch sensor Cm. The device passivation layer 400 may prevent or at least reduce the damage of the touch sensor Cm due to the external impact. For example, the driving touch lines 310 and the sensing touch lines 320 may be covered by the device passivation layer 400. The device passivation layer 400 may be in direct contact with the touch insulating layer 350 at the outside of the first touch electrodes 311, the first bridge electrodes 312 and the second touch electrodes 321. The device passivation layer 400 may include an insulating material. For example, the device passivation layer 400 may include an organic insulating material. The device passivation layer 400 may include a material different from the touch insulating layer 350.

Referring to FIG. 2, various signals to realize an image may be applied to each pixel area PA through the bezel area BZ of the device substrate 110. For example, the bezel area BZ of the device substrate 110 may include a pad area PD in which display pads 104 and touch pads 304 are disposed. The dam 106 may be disposed between the display area AA and the pad area PD. For example, the display pads 104 and the touch pads 304 may be spaced away from the encapsulating unit 140. Thus, in the touch display apparatus according to the embodiment of the present disclosure, it is possible to prevent or at least reduce some of the display pads 104 and/or the touch pads 304 from being unintentionally covered by the organic encapsulation layer 142. Therefore, in the touch display apparatus according to the embodiment of the present disclosure, the distortion of the signal transmitted through the display pads 104 and/or the touch pads 304 may be prevented or at least reduced.

The gate lines GL and/or the data lines DL may be electrically connected to the display pads 104. For example, the data signal applied to each pixel area PA may be transmitted through one of the display pads 104 and one of the data lines DL. The touch pads 304 may be disposed side by side with the display pads 104. For example, the pad area PD may be disposed on a side of the display area AA.

Referring to FIGS. 2, 4 and 5, each of the touch pads 304 may include a lower pad electrode 304a and an upper pad electrode 304b on the lower pad electrode 304a. The touch pads 304 may be formed using a process of forming the pixel driving circuits, the light-emitting devices 130, and the touch sensor Cm. For example, the lower pad electrode 304a may include the same material as the source electrode 124 and the drain electrode 125 of each pixel driving circuit, the upper pad electrode 304b may include the same material as the first touch electrodes 311, the first bridge electrodes 312 and the second touch electrodes 321. The display pads 104 may have the same structure as the touch pads 304. For example, each of the display pads 104 may include a lower pad electrode and an upper pad electrode on the lower pad electrode. The lower pad electrode of each display pad 104 may include the same material as the lower pad electrode 304a of each touch pad 304, and the upper pad electrode of each display pad 104 may include the same material as the upper pad electrode 304b of each touch pad 304. For example, the display pads 104 may be formed simultaneously with the touch pads 304.

The driving touch lines 310 and the sensing touch lines 320 may be electrically connected to the touch pads 304 by touch routing lines 330. The touch routing lines 330 may include first routing lines 331 and second routing lines 332. The second routing lines 332 may be insulated from the first routing lines 331. For example, the second routing lines 332 may be disposed on a layer different from the first routing lines 331. Each of the touch pads 304 may be electrically connected to one of the first routing lines 331 or one of the second routing lines 332.

The first routing lines 331 and the second routing lines 332 may be formed using a process of forming the touch sensor Cm. The second routing lines 332 may include a material different from the first routing lines 331. For example, the first routing lines 331 may include the same material as the second bridge electrodes 322, and the second routing lines 332 may include the same material as the first touch electrodes 311, the first bridge electrodes 312 and the second touch electrodes 321. The first routing lines 331 may be formed simultaneously with the first bridge electrodes 312. For example, the first routing lines 331 may be disposed between the touch buffer layer 200 and the touch insulating layer 350. The second routing lines 332 may be formed simultaneously with the first touch electrodes 311 and the second touch electrodes 321. For example, the second routing lines 332 may be disposed between the touch insulating layer 350 and the device passivation layer 400.

A portion of each second routing line 332 may overlap a corresponding one of the first routing lines 331. For example, a portion of each second routing line 332 extending along an edge of the display area AA may partially overlap one of the first routing lines 331. Thus, in the touch display apparatus according to the embodiment of the present disclosure, an area occupied by the first routing lines 331 and the second routing lines 332 may be reduced. That is, in the touch display apparatus according to the embodiment of the present disclosure, a width of each first routing line 331 and a width of each second routing line 332 may be increased, without increasing the bezel area BZ. Therefore, in the touch display apparatus according to the embodiment of the present disclosure, the resistance of each first routing line 331 and the resistance of each second routing line 332 may be sufficiently low. And, in the touch display apparatus according to the embodiment of the present disclosure, the overall size may be reduced.

The touch insulating layer 350 including an organic insulating material may be disposed between the first routing lines 331 and the second routing lines 332. Thus, in the touch display apparatus according to the embodiment of the present disclosure, a distance between adjacent the first routing line 331 and the second routing line 332 may be relatively increased. That is, in the touch display apparatus according to the embodiment of the present disclosure, the second routing lines 332 may be sufficiency insulated from the first routing lines 331. Therefore, in the touch display apparatus according to the embodiment of the present disclosure, the distortion of the signal applied by the first routing lines 331 due to the signal applied by the second routing lines 332 may be prevented.

Each touch line 310 and 320 of the touch sensor Cm may be electrically connected to one of the first routing lines 331 or one of the second routing lines 332. For example, each driving touch line 310 and each sensing touch line 320 of the touch sensor Cm may be a first touch line electrically connected to one of the first routing lines 331 or a second touch line electrically connected to one of the second routing lines 332. The second touch lines may be disposed between the first touch lines. For example, each of the first touch electrodes 311 may be electrically connected to one of the touch routing lines 331 and 332 disposed on a layer different from that of the first touch electrode 311 adjacent in the first direction, and each of the second touch electrodes 321 may be electrically connected to one of the touch routing lines 331 and 332 disposed on a layer different from that of the second touch electrode 321 adjacent in the second direction. Thus, in the touch display apparatus according to the embodiment of the present disclosure, an overlapping area of the first routing lines 331 and the second routing lines 332 may be maximized. To maximize the overlap area, a center of the first routing line 331 and a center of the second routing line 331 along the first direction overlap. Therefore, in the touch display apparatus according to the embodiment of the present disclosure, an area occupied by the touch routing lines 331 and 332 may be minimized.

A bending area BA may be disposed between the display area AA and the pad area PD. The bending area BA may be an area in which the device substrate 110 is bent. For example, in the touch display apparatus according to the embodiment of the present disclosure, the pad area PD may overlap the display area AA by bending of the bending area BA. The bending area BA may be disposed outside the dam 106. For example, the dam 106 may be disposed between the display area AA and the bending area BA.

The encapsulating unit 140 may be spaced away from the bending area BA. The touch buffer layer 200, the touch insulating layer 350, the device passivation layer 400 and the touch routing lines 330 may not overlap the bending area BA. Thus, in the touch display apparatus according to the embodiment of the present disclosure, the number of layers stacked on the bending area BA may be reduced. Therefore, in the touch display apparatus according to the embodiment of the present disclosure, a bending stress due to a bending of the bending area BA may be minimized That is, in the touch display apparatus according to the embodiment of the present disclosure, the damage due to the bending stress may be minimized.

The touch routing lines 330 may be electrically connected to the touch pads 304 by connecting patterns 107 which cross the bending area BA. For example, each of the connecting patterns 107 may be connected to one of the first routing lines 331 or one of the second routing lines 332. The connecting patterns 107 may include a conductive material. The connecting patterns 107 may be formed using a process of forming the pixel driving circuit and the light-emitting device 130 in each pixel area PA. For example, the connecting patterns 107 may include the source electrode 124 and the drain electrode 125 of each pixel area PA. The connecting patterns 107 may be disposed on the same layer as the source electrode 124 and the drain electrode 125 of each pixel area PA. For example, the connecting patterns 107 may be disposed on the interlayer insulating layer 112.

A crack preventing layer 108 may be disposed on the connecting patterns 107. The crack preventing layer 108 may overlap the bending area BA. For example, a portion of each connecting pattern 107 on the bending area BA may be covered by the crack preventing layer 108. The crack preventing layer 108 may include an insulating material. The crack preventing layer 108 may be formed simultaneously with a layer on the encapsulating unit 140. For example, the crack preventing layer 108 may include the same material as the touch buffer layer 200. Thus, in the touch display apparatus according to the embodiment of the present disclosure, the damage of the connecting patterns 107 due to the bending stress may be prevented.

Each of the first routing lines 331 and the second routing lines 332 may be in direct contact with one of the connecting patterns 107. An end portion of each connecting pattern 107 may be covered by the touch buffer layer 200. For example, each of the first routing lines 331 and each of the second routing lines 332 may be in direct contact with a portion of a corresponding connecting pattern 107 that is located between the touch buffer layer 200 and the crack preventing layer 108. The overlapping portion of the first routing lines 331 and the second routing lines 332 may not overlap the connecting patterns 107. For example, a portion of each second routing line 332 may overlap one of the first routing lines 331 at an area between the display area AA and the connecting patterns 107. Thus, in the touch display apparatus according to the embodiment of the present disclosure, a process of electrically connecting each touch routing line 330 to one of the connecting patterns 107 may be simplified. Therefore, in the touch display apparatus according to the embodiment of the present disclosure, the process efficiency may be improved.

Each of the connecting patterns 107 may be in direct contact with one of the touch pads 304. For example, the connecting patterns 107 may extend on the pad area PD of the device substrate 110. An end portion of each connecting pattern 107 may be disposed on the interlayer insulating layer 112 of the pad area PD.

Accordingly, the touch display apparatus according to the embodiment of the present disclosure may include the encapsulating unit 140 covering the light-emitting devices 130, the touch sensor Cm including the touch electrodes 311 and 321, which are disposed side by side on the encapsulating unit 140, and the touch pads 304 electrically connected to the touch electrodes 311 and 321 by the touch routing lines 330, wherein the touch routing lines 330 may include the first routing lines 331 and the second routing lines 332 disposed on a layer different from the first routing lines 331. Thus, in the touch display apparatus according to the embodiment of the present disclosure, an area occupied by the touch routing lines 330 may be reduced, the overall size may be reduced. And, in the touch display apparatus according to the embodiment of the present disclosure, the resistance of each touch routing lines 330 may be decreased, without increasing of the bezel area BZ. Therefore, in the touch display apparatus according to the embodiment of the present disclosure, the accuracy of the touch sense may be improved, without reducing the display area AA.

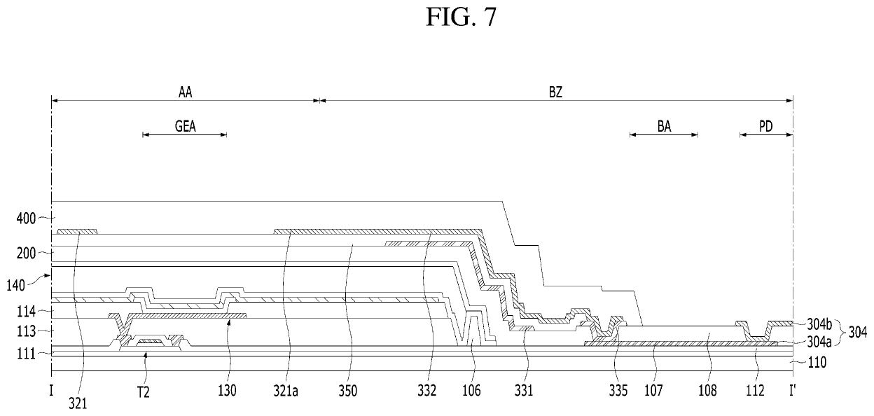

The touch display apparatus according to the embodiment of the present disclosure is described that each of the first routing lines 331 is electrically connected to one of the connecting patterns 107. However, in the touch display apparatus according to another embodiment of the present disclosure, each of the second routing lines 332 may be electrically connected with one of the connecting patterns 107, as shown in FIG. 7. Each of intermediate patterns 335 may be disposed between an end portion of each second routing line 332 and a portion of the corresponding connecting pattern 107. For example, each of the intermediate patterns 335 may be in direct contact with the corresponding second routing line 332 and the corresponding connecting pattern 107. The intermediate patterns 335 may include the same material as the first routing lines 331. For example, an end of each intermediate pattern 335 may be disposed between the touch buffer layer 200 and the touch insulating layer 350.

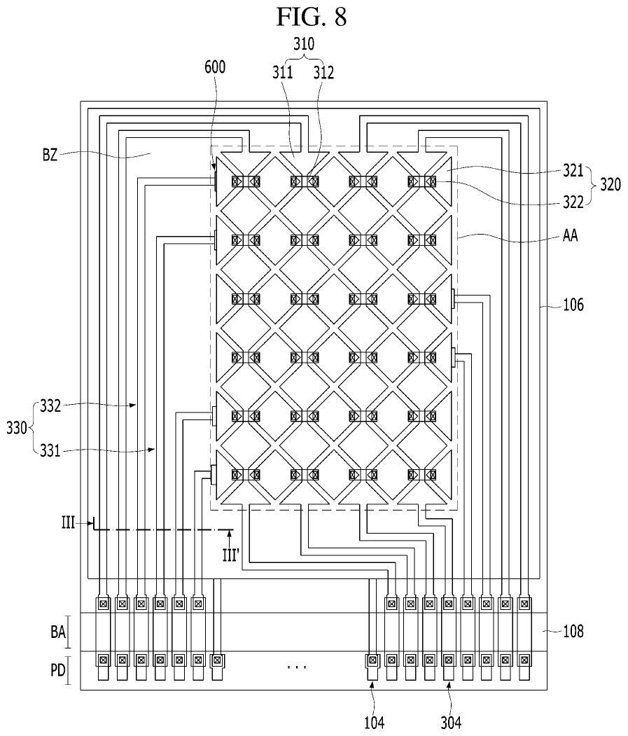

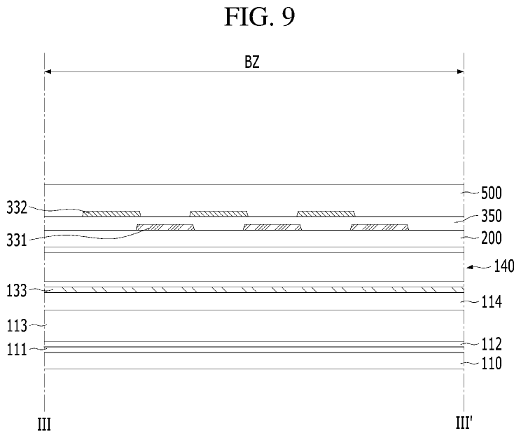

The touch display apparatus according to the embodiment of the present disclosure is described that a portion of each second routing line 332 overlaps one of the first routing lines 331. However, in the touch display apparatus according to another embodiment of the present disclosure, the first routing lines 331 and the second routing lines 332 disposed on a layer different from the first routing lines 331 may be arranged in various ways. For example, in the touch display apparatus according to another embodiment of the present disclosure, the second routing lines 332 may be disposed between the first routing lines 331, as shown in FIGS. 8 and 9. That is, a second routing line from the plurality of second routing lines 332 is between a pair of first routing lines from the plurality of first routing lines 331 in a plan view of the touch display apparatus. The second routing lines 332 may be insulated from the first routing lines 331 by the touch insulating layer 350. Thus, in the touch display apparatus according to another embodiment of the present disclosure, the first routing lines 331 and the second routing lines 332 may be dense. That is, in the touch display apparatus according to another embodiment of the present disclosure, each of the second routing lines 332 may partially overlap adjacent first routing lines 331. For example, a side surface of each second routing line 332 may overlap one of the first routing lines 331. That is, an end a second routing line 332 may overlap an end of a first routing line 331 with the touch insulating layer 350 disposed between the second routing line 332 and the first routing line 331. Therefore, in the touch display apparatus according to another embodiment of the present disclosure, the resistance of each touch routing line 330 may be reduced, without increasing of the bezel area BZ.

The touch display apparatus according to the embodiment of the present disclosure is described that the touch insulating layer 350 includes an organic insulating material. However, in the touch display apparatus according to another embodiment of the present disclosure, the touch insulating layer 350 may be formed of various materials. For example, in the touch display apparatus according to another embodiment of the present disclosure, the touch insulating layer 350 may include an inorganic insulating material, such as silicon oxide (SiO) and silicon nitride (SiN). Alternatively, in the touch display apparatus according to another embodiment of the present disclosure, the touch insulating layer 350 may have a stacked structure of an inorganic insulating layer including an inorganic insulating material and an organic insulating layer including an organic insulating material. Thus, in the touch display apparatus according to another embodiment of the present disclosure, the second routing lines 332 may be effectively insulated from the first routing lines 331. Therefore, in the touch display apparatus according to another embodiment of the present disclosure, an overlapping area of the first routing lines 331 and the second routing lines 332 may be increased.

A thickness difference by the first routing lines 331 may be removed by the touch insulating layer 350. For example, an upper surface of the touch insulating layer 350 opposite to the device substrate 110 may be a flat surface. Thus, in the touch display apparatus according to another embodiment of the present disclosure, the damage of the second routing lines 332 due to the thickness of each first routing line 331 may be prevented. For example, in the touch display apparatus according to another embodiment of the present disclosure, partial breakage of the second routing lines 332 due to a height deviation of the touch insulating layer 350 may be prevented. That is, in the touch display apparatus according to another embodiment of the present disclosure, the degree of freedom for the thickness of the first routing lines 331 and the second routing lines 332 may be improved. Therefore, in the touch display apparatus according to another embodiment of the present disclosure, the resistance of the first routing lines 331 and the second routing lines 332 may be significantly reduced.

In the touch display apparatus according to another embodiment of the present disclosure, each of the sensing touch lines 320 may be connected to the corresponding touch routing line 330 by one of compensating patterns 600. The compensating patterns 600 may compensate a difference between the touch routing lines 330. For example, an area of each compensating pattern 600 may be proportional to a straight distance between the pad area PD and the corresponding sensing touch line 320. Thus, in the touch display apparatus according to another embodiment of the present disclosure, the deviation of the touch sensing signal due to a capacitance difference between the touch routing lines 330 may be prevented. Therefore, in the touch display apparatus according to another embodiment of the present disclosure, the accuracy for the touch of the user and/or the tool may be improved.

In the result, the touch display apparatus according to the embodiments of the present disclosure may comprise the encapsulating unit covering the light-emitting device, the touch lines on the encapsulating unit and the touch routing lines electrically connecting each touch line to one of the touch pads, wherein the touch routing lines may include the first routing lines and the second routing lines, and wherein the second routing lines may be disposed on a layer different from the first routing lines. Thus, in the touch display apparatus according to the embodiments of the present disclosure, an area occupied by the touch routing liens may be reduced. Thereby, in the touch display apparatus according to the embodiments of the present disclosure, the accuracy of the touch sense may be improved, without reducing the display area.

What is claimed is:

1. A touch display apparatus comprising:
a device substrate;
a plurality of light-emitting devices on the device substrate;
an encapsulating layer on the plurality of light-emitting;
a touch sensor including a plurality of touch electrodes on the encapsulating layer;
a plurality of touch pads on the device substrate, the plurality of touch pads non-overlapping with the encapsulating layer;
a plurality of touch routing lines, each touch routing line electrically connecting a corresponding touch electrode from the plurality of touch electrodes to a corresponding touch pad from the plurality of touch pads,
wherein the plurality of touch routing lines include a plurality of first routing lines and a plurality of second routing lines that are on a different layer from the plurality of first routing lines, the plurality of second routing lines insulated from the plurality of first routing lines.

2. The touch display apparatus according to claim 1, wherein each of the plurality of touch pads is electrically connected to a corresponding one of the plurality of first routing lines or a corresponding one of the plurality of second routing lines.

3. The touch display apparatus according to claim 1, wherein the plurality of second routing lines include a material that is different from a material included in the plurality of first routing lines.

4. The touch display apparatus according to claim 3, wherein the material included in the plurality of second routing lines is the same as a material included in the plurality of touch electrodes.

5. The touch display apparatus according to claim 1, wherein a portion of each of the plurality of second routing lines overlaps with a portion of a corresponding one of the plurality of first routing lines.

6. The touch display apparatus according to claim 5, wherein the portion of each of the plurality of second routing line that overlaps with the portion of the corresponding one of the plurality of first routing lines extends in a direction of an edge of a display area that includes the plurality of light-emitting devices.

7. The touch display apparatus according to claim 1, further comprising:
a plurality of connecting patterns across a bending area, the plurality of connecting patterns between the encapsulating layer and the plurality of touch pads,
wherein each of the plurality of connecting patterns is electrically connected to a corresponding one of the plurality of first routing lines or a corresponding one of the second routing lines.

8. The touch display apparatus according to claim 7, further comprising:
a plurality of intermediate patterns, each intermediate pattern between a corresponding second routing line from the plurality of second routing lines and a corresponding one of the plurality of connecting patterns,
wherein the plurality of first routing lines are between the device substrate and the plurality of second routing lines, and the plurality of intermediate patterns include a same material as the plurality of first routing lines.

9. A touch display apparatus comprising:
a device substrate;
a plurality of light-emitting devices on the device substrate;
an encapsulating layer on the plurality of light-emitting devices;
a plurality of touch pads on the device substrate, the plurality of touch pads non-overlapping with the encapsulating layer;
a plurality of first touch lines on the encapsulating layer, the plurality of first touch lines including a plurality of first touch electrodes along in a first direction;
a plurality of first routing lines, each first routing line electrically connecting a corresponding first touch line from the plurality of first touch lines to a corresponding touch pad from the plurality of touch pads;
a plurality of second touch lines between the plurality of first touch lines, the plurality of second touch lines including a plurality of second touch electrodes that are connected in a second direction that is different from the first direction; and
a plurality of second routing lines, each second routing line electrically connecting a corresponding second touch line from the plurality of second touch lines to a corresponding touch pad from the plurality of touch pads,
wherein the plurality of second routing lines are on a different layer than the plurality of first routing lines.

10. The touch display apparatus according to claim 9, wherein the plurality of first touch lines and the plurality of second touch lines are non-overlapping with the plurality of light-emitting devices.

11. The touch display apparatus according to claim 9, wherein a second routing line from the plurality of second routing lines is between a pair of first routing lines from the plurality of first routing lines.

12. The touch display apparatus according to claim 11, wherein a first end of the second routing line overlaps an end of a first routing line from the pair of first routing lines and a second end of the second routing line that is opposite the first end overlaps an end of a another first routing line from the pair of first routing lines.

13. The touch display apparatus according to claim 9, wherein the plurality of first touch lines include a plurality of first bridge electrodes that electrically connect together the plurality of first touch electrodes, and the plurality of second touch lines include a plurality of second bridge electrodes that electrically connect together the plurality of second touch electrodes,
wherein the plurality of first routing lines include a same material as the plurality of first bridge electrodes.

14. The touch display apparatus according to claim 13, further comprising:
a touch insulating layer between the plurality of first routing lines and the plurality of second routing lines,
wherein the plurality of first routing lines and the plurality of first bridge electrodes are between the encapsulating layer and the touch insulating layer.

15. The touch display apparatus according to claim 13, wherein the plurality of second routing lines include a same material as the plurality of first touch electrodes.

16. A touch display apparatus comprising:
a substrate including a display area and a pad area;
a plurality of pads in the pad area, the plurality of pads including a first pad and a second pad;
a plurality of light-emitting devices on the display area;
a touch sensor including a plurality of touch electrodes on the display area, the plurality of touch electrodes including a first touch electrode and a second touch electrode;
a first routing line connected to the first touch electrode and the first touch pad;
a second routing line connected to the second touch electrode and the second touch pad,
wherein a portion of the first routing line at least partially overlaps a portion of the second routing line in a direction along a length of the display area in a plan view of the touch display apparatus.

17. The touch display apparatus of claim 16, wherein a center of the portion of the first routing line overlaps a center of the portion of the second routing line in the plan view.

18. The touch display apparatus of claim 16, wherein an end of the portion of the first routing line overlaps an end of the portion of the second routing line.

19. The touch display apparatus of claim 16, further comprising:
an insulating layer between the first routing line and the second routing line.

20. The touch display apparatus of claim 16, wherein the first routing line and the second routing line include different materials.
